(19) United States
(12) Patent Application Publication
(10) Pub. No.: US 2009/0072406 A1
(43) Pub. Date: Mar. 19, 2009

(54) INTERCONNECT STRUCTURE WITH IMPROVED ELECTROMIGRATION RESISTANCE AND METHOD OF FABRICATING SAME

(75) Inventors: Chih-Chao Yang, Glenmont, NY (US); Ping-Chuan Wang, Hopewell Junction, NY (US); Kaushik Chanda, Fishkill, NY (US)

Correspondence Address: SCULLY, SCOTT, MURPHY & PRESSER, P.C., 400 GARDEN CITY PLAZA, Suite 300, GARDEN CITY, NY, 11530, US

(73) Assignee: INTERNATIONAL BUSINESS MACHINES CORPORATION, Armonk, NY (US)

(21) Appl. No.: 11/856,970

(22) Filed: Sep. 18, 2007

(51) Int. Cl. H01L 21/31

(52) U.S. Cl. 257/761; 257/E21.24

(57) ABSTRACT

An interconnect structure in which the electromigration resistance thereof is improved without introducing a gouging feature within the interconnect structure is provided. The interconnect structure includes a metallic interfacial layer that is at least horizontally present at the bottom of an opening located within a second dielectric material that is located atop a first dielectric material that includes a first conductive material embedded therein. The metallic interfacial layer does not form an alloy with an underlying conductive material that is embedded within the first dielectric material. In some embodiments of the present invention, the metallic interfacial layer is also present on exposed sidewalls of the second dielectric material that is located atop the first dielectric material. Atop the metallic interfacial layer there is present a diffusion barrier liner. In some embodiments, the diffusion barrier liner includes a lower layer of a metallic nitride and an upper layer of a metal. In accordance with the present invention, the metallic interfacial layer also does not form an alloy with any portion of the diffusion barrier liner.

### FIELD OF THE INVENTION

The present invention relates to a semiconductor interconnect structure, and a method of fabricating the same. More particularly, the present invention relates to a semiconductor interconnect structure having improved electromigration (EM) resistance without including a gouging feature within a contact area and to a method of fabricating such an interconnect structure.

### BACKGROUND OF THE INVENTION

Generally, semiconductor devices include a plurality of circuits that form an integrated circuit (IC) fabricated on a semiconductor substrate. A complex network of signal paths will normally be routed to connect the circuit elements distributed on the surface of the substrate. Efficient routing of these signals across the device requires formation of multilevel (i.e., multilayered) schemes, such as, for example, single or dual damascene wiring structures. The wiring structure typically, but not necessarily always, includes copper (Cu) since Cu-based interconnect wiring structures provide higher speed signal transmission between large numbers of transistors on a complex semiconductor chip as compared with aluminum (Al)-based interconnect structures.

Within a typical interconnect structure, metal vias run perpendicular to the semiconductor substrate and metal lines run parallel to the semiconductor substrate. Further enhancement of the signal speed and reduction of signals in adjacent metal lines (“known as crosstalk”) are achieved in today's interconnect structures by embedding the metal lines and metal vias (e.g., conductive features) in a dielectric material having a dielectric constant of less than 4.0.

In semiconductor interconnect structures, electromigration (EM) has been identified as one metal failure mechanism. EM is one of the worst reliability concerns for very large scale integration (VLSI) circuits. The problem not only needs to be overcome during the process development period in order to qualify the process, but it persists throughout the lifetime of the chip. Voids are created inside the metal conductor of an interconnect structure edge due to the metal movement that is caused by the high density of current flow. Interconnect structures having electromigration resistance are thus highly desirable.

Reference is made to FIG. 1 which illustrates a prior art interconnect structure having a flat via bottom. Specifically, the prior art interconnect structure includes a first dielectric material 10 which includes a conductive material 18, e.g., Cu, embedded therein. The conductive material 18 is spaced apart from the first dielectric material 10 by a bilayer diffusion barrier liner that includes a lower layer 14 of a metallic nitride, e.g., TaN, and an upper layer 16 of a metal such as, for example, Ta. The bilayer diffusion barrier liner lines an opening that was formed into the first dielectric material 10 prior to filling the same with conductive material 18.

Atop the first dielectric material 10, is a second dielectric material 10′ that includes a conductive material 18′ that is embedded within. The conductive material 18′ is located within a line opening 20 and via opening 22 that are formed into the second dielectric material 10′. The conductive material 18′ is spaced apart from the second dielectric material 10′ by another bilayer diffusion barrier layer that includes a lower layer 14′ of a metallic nitride, e.g., TaN, and an upper layer 16′ of a metal such as, for example, Ta. A dielectric capping layer 24 is located between the first and second dielectric layers and a portion of the dielectric capping layer 24 extends upon an upper surface of the conductive material 18 that is present in the first dielectric material 10.

The prior art structure shown in FIG. 1 has a flat via bottom (designated by A in the drawing) that is contact with the conductive material 18 within the first dielectric material 10. The prior art interconnect structure shown in FIG. 1 has a high degree of EM associated therewith due to the limited contact area between the via opening 22 and underlying interconnect 18. The limited contact area usually results in current crowding and is the weakest site for void nucleation due to EM effect.

FIG. 2 shows another prior art interconnect structure which is basically the same as that shown in FIG. 1 except that this prior art interconnect structure includes a via gouging feature (designed by B in FIG. 2). The presence of the via gouging feature B in the interconnect structure, which increases the via contact area, improves electromigration resistance of such an interconnect structure as compared with the interconnect shown in FIG. 1.

Despite improving the electromigration resistance of the interconnect structure, the via gouging feature B shown in FIG. 2 is formed by processes that always result in profile damage. By “profile damage” it is meant patterned dielectric damage, specifically at the bottom of the line opening 20, from a physical gaseous bombardment, which is used to create the via gouging feature.

In view of the above, there is a need for providing interconnect structures in which the electromigration resistance is improved without introducing a gouging feature within the interconnect structure.

### SUMMARY OF THE INVENTION

The present invention provides an interconnect structure in which the electromigration resistance thereof is improved without introducing a gouging feature within the interconnect structure. The interconnect structure includes a metallic interfacial layer that is at least horizontally present at the bottom of an opening, preferably, but not necessarily always, a via opening, located within a second dielectric material that is located atop a first dielectric material that includes a first conductive material embedded therein. The metallic interfacial layer does not form an alloy with an underlying conductive material that is embedded within the first dielectric material. In some embodiments of the present invention, the metallic interfacial layer is also present on exposed sidewalls of the second dielectric material that is located atop the first dielectric material. Atop the metallic interfacial layer there is present a diffusion barrier liner. In some embodiments, the diffusion barrier liner includes a lower layer of a metallic nitride and an upper layer of a metal. In accordance with the present invention, the metallic interfacial layer also does not form an alloy with any portion of the diffusion barrier liner.

In general terms, an interconnect structure is provided that includes:

a first dielectric material having a first conductive material embedded therein; and
a second dielectric material located atop the first dielectric material, said second dielectric material includes at least one conductively filled opening that is located above said first conductive material, wherein said at least one conductively filled opening and said first conductive material are horizontally separated by a metallic interfacial layer which is present at least within a bottom portion of said at least one conductively filled opening.

In one embodiment of the present invention, the metallic interfacial layer is located only within a bottom portion of said at least one conductively filled opening. In another embodiment of the present invention, the metallic interfacial layer is also present on exposed sidewalls of the second dielectric material that laterally abut the bottom portion of the at least one conductively filled opening.

The at least one opening is any opening that is formed into the second dielectric material which extends to and exposes a surface of the conductive material that is present in the first dielectric material. The at least one opening includes, but is not limited to a via opening, a line opening, or a combined via and line opening. In a preferred embodiment of the present invention, the at least one opening is a combined via opening and line opening in which the via is located directly beneath the line.

The metallic interfacial layer employed in the present invention includes any conductive metal including metals from Group VB or VIII of the Periodic Table of Elements. Examples of Group VB metals that are conductive include V, Nb and Ta. Examples of Group VIII metals that are conductive include Fe, Co, Ni, Ru, Rh, Pd, Os, Ir and Pt. In a preferred embodiment of the present invention, the metallic interfacial layer comprises Ta, Ru, Ir or Co. In some embodiments of the present invention, the metallic interfacial layer comprises In.

In addition to providing an interconnect structure, the present invention also provides a method of fabricating such an interconnect structure. The method of the present invention, which is compatible with existing interconnect processing, includes:

forming a first dielectric material having a first conductive material embedded therein;
forming a second dielectric material atop the first dielectric material, said second dielectric material has at least one opening that extends to an upper surface of the first conductive material;
forming a metallic interfacial layer at least within a bottom portion of said at least one opening, said metallic interfacial layer is located at least on said upper surface of said first conductive material;
forming a diffusion barrier liner within said at least one opening and on at least an upper surface of said metallic interfacial layer; and
filling said at least one via opening with a second conductive material.

In one embodiment of the present invention, the metallic interfacial layer is formed by a selective deposition process. In another embodiment of the present invention, the metallic interfacial layer is formed by a non-selective deposition process.

### BRIEF DESCRIPTION OF THE DRAWINGS

FIG. 1 is a pictorial representation (through a cross sectional view) depicting a prior art interconnect structure having a flat bottom via.

FIG. 2 is a pictorial representation (through a cross sectional view) depicting a prior art interconnect structure in which the via contact area has been increased by a gouging feature.

FIGS. 3A and 3B are pictorial representations (through cross sectional views) depicting interconnect structures of the present invention.

FIGS. 4-7 are pictorial representations (through cross sectional views) illustrating the basic processing step that are employed in fabricating the inventive interconnect structure shown in FIG. 3A.

FIGS. 8-10 are pictorial representations (through cross sectional views) illustrating the basic processing step that are employed in fabricating the inventive interconnect structure shown in FIG. 3B.

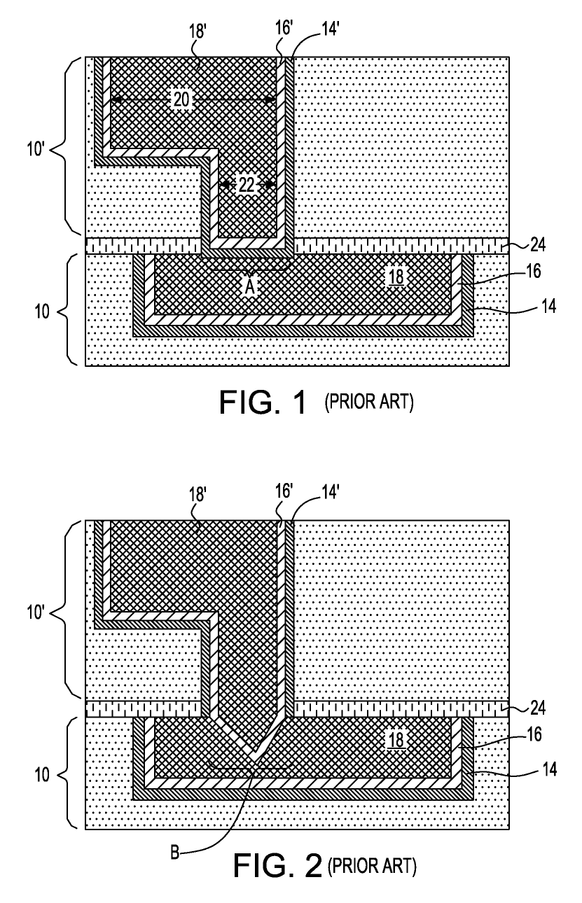

### DETAILED DESCRIPTION OF THE INVENTION

The present invention, which provides an interconnect structure having improved electromigration (EM) resistance without including a gouging feature and a method of forming the same, will now be described in greater detail by referring to the following discussion and drawings that accompany the present application. It is noted that the drawings of the present application are provided for illustrative purposes only and, as such, the drawings are not drawn to scale.

In the following description, numerous specific details are set forth, such as particular structures, components, materials, dimensions, processing steps and techniques, in order to provide a thorough understanding of the present invention. However, it will be appreciated by one of ordinary skill in the art that the invention may be practiced without these specific details. In other instances, well-known structures or processing steps have not been described in detail in order to avoid obscuring the invention.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

As stated above, the present invention provides an interconnect structure having improved EM resistance. The improved EM resistance is achieved in the present invention without the need of introducing a gouging feature within the interconnect structure.

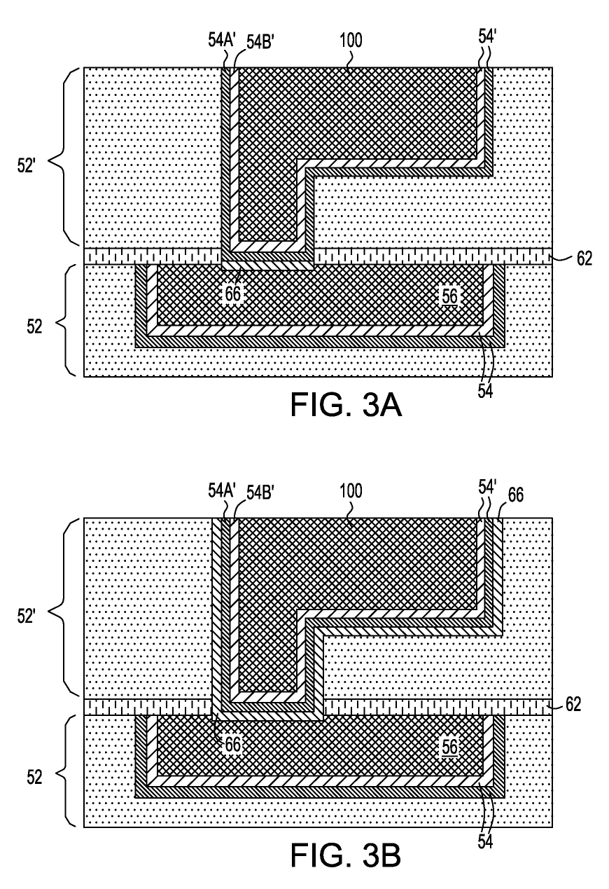

FIGS. 3A-3B illustrate various embodiments of the present invention. Specifically, FIG. 3A-3B illustrate interconnect structures of the present invention in which a metallic interfacial layer is at least horizontally present at the bottom of an opening located within a second dielectric material that is located atop a first dielectric material that includes a first conductive material embedded therein. In the interconnect structure shown in FIG. 3A, the metallic interfacial layer is located only within the bottom portion of the opening. In the interconnect structure shown in FIG. 3B, the metallic interfacial layer is located within the bottom portion of the opening and on sidewalls of the second dielectric material that abut the bottom portion of the opening.

In particular, the interconnect structures shown in FIGS. 3A and 3B both include a first dielectric material 52 having a first conductive material 56 embedded therein. The first conductive material 56 is spaced apart from the first dielectric material 52 by a first diffusion barrier liner 54. Each structure also includes a second dielectric material 52′ located atop the first dielectric material 52. A dielectric capping layer 62 is typically located between the first dielectric material 52 and the second dielectric material 52′. As shown, portions of the dielectric capping layer 62 are located on the upper surface of the first conductive material 56.

The second dielectric material 52′ includes at least one conductively filled opening 100 that is located above the first conductive material 56. The at least one conductive filled opening 100 extends to and exposes an upper surface of the first conductive material 56 present within the first dielectric material 52. The at least one conductively filled opening 100 and the first conductive material 56 are horizontally separated by a metallic interfacial layer 66. That is, the metallic interfacial layer 66 is present at least within a bottom portion of the at least one conductively filled opening 100. In FIG. 3A, the metallic interfacial layer 66 is located only within the bottom portion of the at least one conductively filled opening 100. In FIG. 3B, the metallic interfacial layer 66 is also present on sidewalls of the second dielectric material 52′ that laterally abut the bottom portion of the at least one conductively filled opening 100.

Each interconnect structure also includes a second diffusion barrier liner 54′ that is located between said second dielectric material 52′ and that at least one conductively filled opening 100. The second diffusion barrier liner 54′ may include a lower layer 54A′ of a metallic nitride such as, for example, TaN, and an upper layer 54B′ of a metal such as, for example, Ta.

The at least one conductively filled opening 100 may comprise a via opening, a line opening or a combined via and line opening. Preferably, and as illustrated, the at least one conductively filled opening 100 includes a combined via opening and a line opening, in which the line opening is located directly atop the via opening.

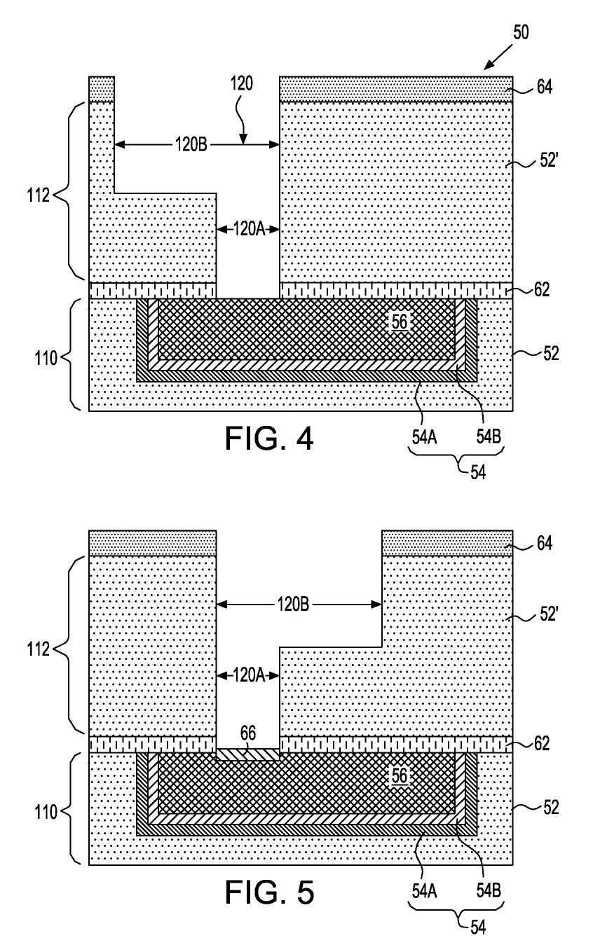

Reference is now made to FIGS. 4-7 which illustrate basic processing steps that are employed in the present invention for fabricating the interconnect structure shown in FIG. 3A.

FIG. 4 illustrates an initial and partially formed interconnect structure 50 that is employed in the present invention. In particular, the initial and partially formed interconnect structure 50 is a multilevel interconnect structure including a lower interconnect level 110 and an upper interconnect level 112 that are separated in part by dielectric capping layer 62. The lower interconnect level 10, which may be located above a semiconductor substrate including one or more semiconductor devices, comprises a first dielectric material 52 having at least one conductive material (i.e., conductive feature or conductive region) 56 that is separated from the first dielectric material 52 by a first diffusion barrier liner 54. The first diffusion barrier 54 may comprise, in some embodiments, a lower layer 54A of a metallic nitride, and an upper layer 54B of a metal. The upper interconnect level 112 comprises a second dielectric material 52′ that has at least one opening 120.

The at least one opening 120 may comprise a via opening, a line opening or a combined via and line opening. Preferably, and as illustrated, the at least one opening 120 includes a combined via opening and a line opening, in which the line opening is located directly atop the via opening. In the drawing, reference numeral 120A denotes the via opening, while reference numeral 120B denotes the line opening. It is noted that the at least one opening 120 employed in the present invention extends to and exposes and upper surface of the first conductive material 56 located in the first dielectric material 52.

The initial interconnect structure 50 shown in FIG. 4 is made utilizing standard interconnect processing which is well known in the art. For example, the initial interconnect structure 50 can be formed by first applying the first dielectric material 52 to a surface of a substrate (not shown). The substrate, which is not shown, may comprise a semiconducting material, an insulating material, a conductive material or any combination thereof. When the substrate is comprised of a semiconducting material, any semiconductor such as Si, SiGe, SiGeC, SiC, Ge alloys, GaAs, InAs, InP and other III/V or IIVI compound semiconductors may be used. In addition to these listed types of semiconducting materials, the present invention also contemplates cases in which the semiconductor substrate is a layered semiconductor such as, for example, Si/SiGe, Si/SiC, silicon-on-insulators (SOIs) or silicon germanium-on-insulators (SGOIs).

When the substrate is an insulating material, the insulating material can be an organic insulator, an inorganic insulator or a combination thereof including multilayers. When the substrate is a conducting material, the substrate may include, for example, polySi, an elemental metal, alloys of elemental metals, a metal silicide, a metal nitride or combinations thereof including multilayers. When the substrate comprises a semiconducting material, one or more semiconductor devices such as, for example, complementary metal oxide semiconductor (CMOS) devices can be fabricated thereon.

The first dielectric material 52 may comprise any interlevel or intralevel dielectric including inorganic dielectrics or organic dielectrics. The first dielectric material 52 may be porous or non-porous. Some examples of suitable dielectrics that can be used as the first dielectric material 52 include, but are not limited to SiO₂, silsesquioxanes, C doped oxides (i.e., organosilicates) that include atoms of Si, C, O and H, thermosetting polyarylene ethers, or multilayers thereof. The term “polyarylene” is used in this application to denote aryl moieties or inertly substituted aryl moieties which are linked together by bonds, fused rings, or inert linking groups such as, for example, oxygen, sulfur, sulfone, sulfoxide, carbonyl and the like.

The first dielectric material 52 typically has a dielectric constant that is about 4.0 or less, with a dielectric constant of about 2.8 or less being even more typical. These dielectrics generally have a lower parasitic crosstalk as compared with dielectric materials that have a higher dielectric constant than 4.0. The thickness of the first dielectric material 52 may vary depending upon the dielectric material used as well as the exact number of dielectrics within the lower interconnect level 110. Typically, and for normal interconnect structures, the first dielectric material 52 has a thickness from about 200 to about 450 nm.

The lower interconnect level 110 also has at least one first conductive material 56 that is embedded in (i.e., located within) the first dielectric material 52. The first conductive material 56 (which may also be referred to as a conductive region or conductive feature) is separated from the first dielectric material 52 by a first diffusion barrier liner 54. The embedded first conductive material 56 is formed by first providing at least one opening in into the first dielectric material 52 by lithography (i.e., applying a photoresist to the surface of the first dielectric material 52, exposing the photoresist to a desired pattern of radiation, and developing the exposed resist utilizing a conventional resist developer) and etching (dry etching or wet etching). The etched opening is first filled with the first diffusion barrier liner 54 and then with the first conductive material 56. The first diffusion barrier liner 54, which may comprise Ta, TaN, Ti, TiN, Ru, RuTaN, RuTa, W, WN or any other material that can serve as a barrier to prevent conductive material from diffusing there through, is formed by a deposition process such as, for example, atomic layer deposition (ALD), chemical vapor deposition (CVD), plasma enhanced chemical vapor deposition (PECVD), physical vapor deposition (PVD), sputtering, chemical solution deposition, or plating. In some embodiments (not shown), the first diffusion barrier liner 54 may comprise a combination of layers including a lower layer 54A of a metallic nitride and an upper layer 54B of a metal.

The thickness of the first diffusion barrier liner 54 may vary depending on the exact means of the deposition process employed as well as the material and number of layers employed. Typically, the first diffusion barrier liner 54 has a thickness from about 4 to about 40 nm, with a thickness from about 7 to about 20 nm being more typical.

Following the formation of the first diffusion barrier liner 54, the remaining region of the opening within the first dielectric material 52 is filled with a first conductive material 56 forming a conductive feature. The first conductive material 56 used in forming the conductive feature includes, for example, polySi, a conductive metal, an alloy comprising at least one conductive metal, a conductive metal silicide or combinations thereof. Preferably, the first conductive material 56 that is used in forming the conductive feature is a conductive metal such as Cu, W or Al, with Cu or a Cu alloy (such as AlCu) being highly preferred in the present invention. The conductive material is filled into the remaining opening in the first dielectric material 52 utilizing a conventional deposition process including, but not limited to CVD, PECVD, sputtering, chemical solution deposition or plating. After deposition, a conventional planarization process such as, for example, chemical mechanical polishing (CMP) can be used to provide a structure in which the first diffusion barrier liner 54 and the first conductive material 56 each have an upper surface that is substantially coplanar with the upper surface of the first dielectric material 52.

After forming the at least one conductive material 56, the dielectric capping layer 62 is formed on the surface of the lower interconnect level 110 utilizing a conventional deposition process such as, for example, CVD, PECVD, chemical solution deposition, or evaporation. The dielectric capping layer 62 comprises any suitable dielectric capping material such as, for example, SiC, Si₄NH₃, SiO₂, a carbon doped oxide, a nitrogen and hydrogen doped silicon carbide SiC(N,H) or multilayers thereof. The thickness of the dielectric capping layer 62 may vary depending on the technique used to form the same as well as the material make-up of the layer. Typically, the dielectric capping layer 62 has a thickness from about 15 to about 55 nm, with a thickness from about 25 to about 45 nm being more typical.

Next, the upper interconnect level 112 is formed by applying the second dielectric material 52′ to the upper exposed surface of the dielectric capping layer 62. The second dielectric material 52′ may comprise the same or different, preferably the same, dielectric material as that of the first dielectric material 52 of the lower interconnect level 110. The processing techniques and thickness ranges for the first dielectric material 52 are also applicable here for the second dielectric material 52′.

A hard mask 64 is then formed atop the second dielectric material 52′ and is subsequently used as both a pattern mask and as an etch mask. The hard mask 64 includes at least one dielectric material such as, for example, an oxide, nitride or an oxynitride. The hard mask 64 typically comprises an oxide of silicon or a nitride of silicon. The hard mask 64 is formed utilizing a conventional deposition process including, for example, CVD, PECVD, chemical solution deposition, evaporation and atomic layer deposition.

Next, at least one opening 120 is formed into the second dielectric material 52′ utilizing lithography, as described above, and etching. The etching may comprise a dry etching process, a wet chemical etching process or a combination thereof. The term “dry etching” is used herein to denote an etching technique such as reactive-ion etching, ion beam etching, plasma etching or laser ablation. The at least one opening 120 extends to and exposes a surface of the first conductive material 56 within the first dielectric material 52. During the etching process, the pattern is first transferred into the hard mask 64, the photoresist is then removed by a conventional stripping process such as ashing, and thereafter the pattern is transferred to the second dielectric material and then to the dielectric capping layer 62 (i.e., the dielectric capping layer is opened exposing a surface of the first conductive material 56).

FIG. 5 illustrates the interconnect structure of FIG. 4 after formation of an metallic interfacial layer 66 only within a bottom portion of the at least one opening 120 such that the metallic interfacial layer 66 is present only on the exposed surface of the first conductive material 56. The metallic interfacial layer 66 employed in the present invention includes any conductive metal including metals from Group VB or VIII of the Periodic Table of Elements. Examples of Group VB metals that are conductive include V, Nb and Ta. Examples of Group VIII metals that are conductive include Fe, Co, Ni, Ru, Rh, Pd, Os, Ir and Pt. In a preferred embodiment of the present invention, the metallic interfacial layer 66 comprises Ta, Ru, Ir or Co. In some embodiments of the present invention, the metallic interfacial layer 66 comprises In.

In the specific embodiment illustrated, the metallic interfacial layer 66 is formed utilizing a selective deposition process such as, for example, CVD, ALD and electroless plating.

The thickness of the metallic interfacial layer 66 that is formed may vary depending of the type of selective deposition process employed as well as the material of the metallic interfacial layer 66 itself. Typically, the metallic interfacial layer 66 has a thickness from about 1 to about 20 nm, with a thickness from about 5 to about 10 nm being even more typical.

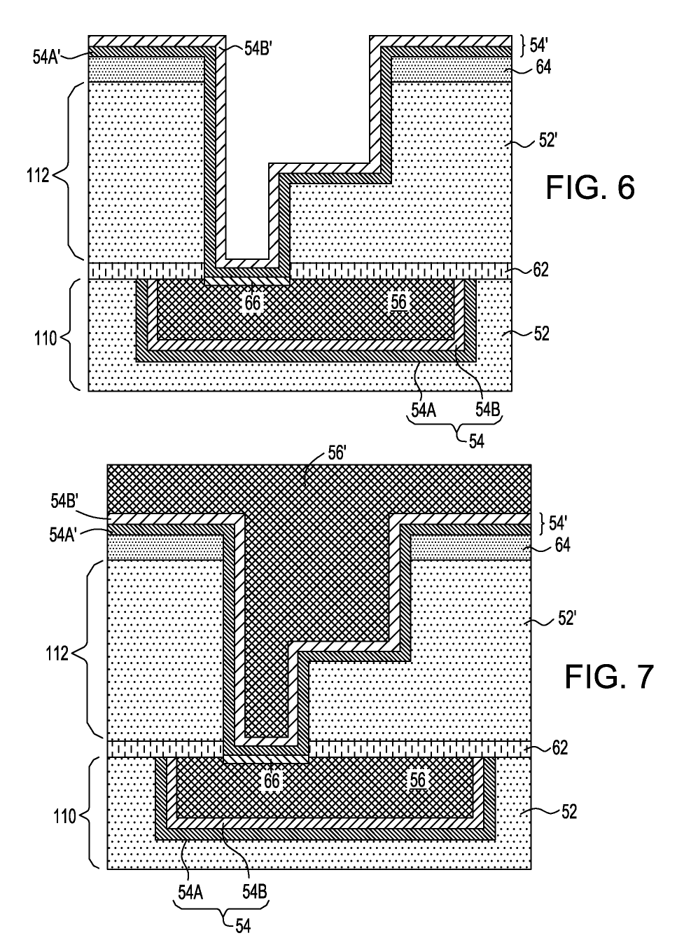

FIG. 6 shows the interconnect structure of FIG. 5 after formation of a second diffusion barrier liner 54′. In the embodiment shown, the second diffusion barrier liner 54′ includes a lower layer 54A′ of a metallic nitride (e.g., TaN, TiN, RuTaN or WN) and an upper layer 54B′ of a metal (e.g., Ta, Ti, Ru, RuTa or W). Although such an embodiment is shown and illustrated that present invention also contemplates embodiments in which the second diffusion barrier liner 54′ is comprised of a single layer instead of a bilayer as shown in FIG. 6. The second diffusion barrier liner 54′ is formed utilizing one of the above mentioned techniques used in forming the first diffusion barrier liner and the same diffusion barrier materials can be present within the second diffusion barrier liner 54′ as the first diffusion barrier liner 54. It is also noted that the thickness of the second diffusion barrier liner 54′ is also within the thickness range reported above for the first diffusion barrier liner 54. It is noted that the second diffusion barrier liner 54′ is located atop the upper surface of the patterned hard mask 64.

FIG. 7 illustrates the interconnect structure of FIG. 6 after filling the at least one opening 120 with a second conductive material 56′. The second conductive material 56′ may comprise the same or different conductive material as the first conductive material 56. Preferably, the first conductive material 56 and the second conductive material 56′ are comprised of a Cu-containing conductive material. As is shown, the filling step also forms the second conductive material 56′ outside each of the openings present in the second dielectric material 52.

Next, a planarization process including chemical mechanical polishing and/or grinding, is employed to provide the planar structure shown in FIG. 3A. During the planarization process, the hard mask 64 is removed from the structure.

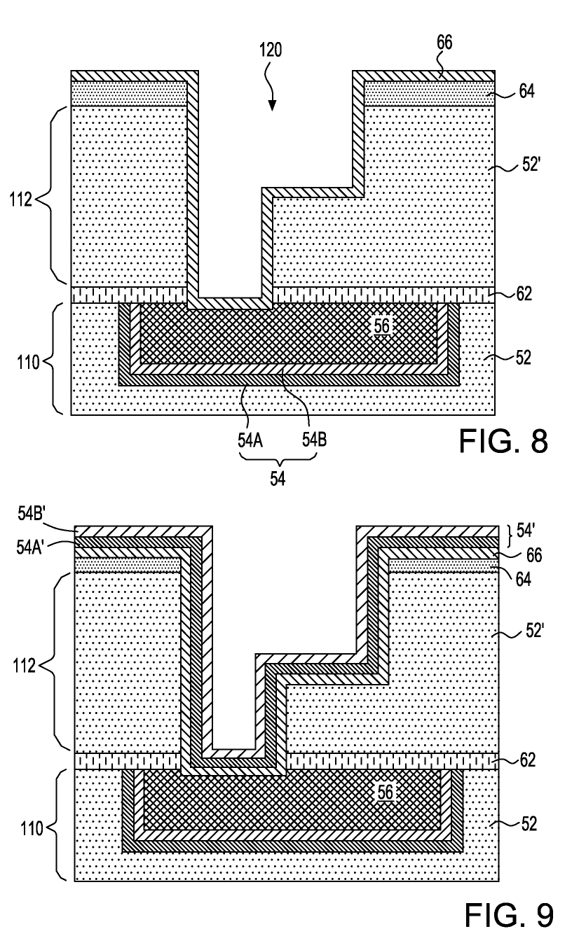

FIGS. 8-10 illustrates a second embodiment of the present invention which provides the structure shown in FIG. 3B. In the second embodiment the initial and partially formed interconnect structure 50 is first provided as described above. FIG. 8 illustrates the structure of FIG. 4 after providing the metallic interfacial layer 66 to all of the exposed surfaces. In this embodiment of the present invention, a non-selective deposition process such as, for example, PVD, iPVD (ionized physical vapor deposition; an advanced type of PVD which provides better/improved step coverage as compared to PVD), CVD, PECVD and ALD, is employed.

FIG. 9 illustrates the structure of FIG. 8 after forming a second diffusion barrier liner 54′ thereon. The composition and thickness of second diffusion barrier liner 54′ as well as the process used in forming the same are as described above in the first embodiment.

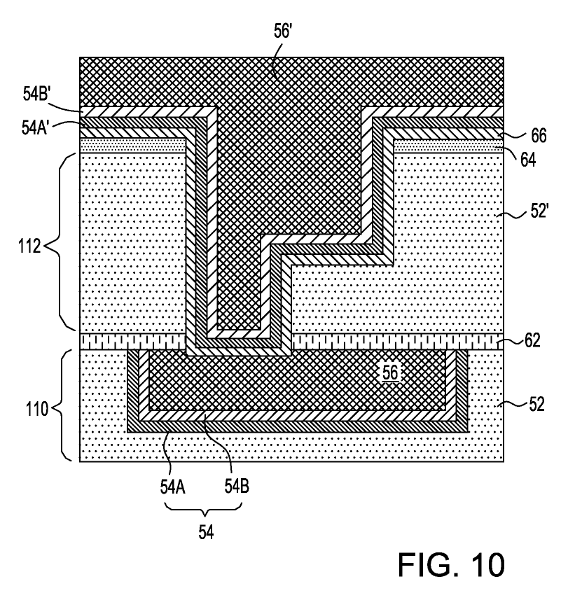

FIG. 10 illustrates the structure of FIG. 9 after filling the opening with a second conductive material 56′. The composition and thickness of second conductive material diffusion barrier liner 56′ as well as the process used in forming the same are as described above in the first embodiment.

After providing the structure shown in FIG. 10, a planarization process is employed to provide the interconnect structure shown in FIG. 3B.

While the present invention has been particularly shown and described with respect to preferred embodiments thereof, it will be understood by those skilled in the art that the foregoing and other changes in forms and details may be made without departing from the spirit and scope of the present invention. It is therefore intended that the present invention not be limited to the exact forms and details described and illustrated, but fall within the scope of the appended claims.

1. An interconnect structure is provided that includes:
a first dielectric material having a first conductive material embedded therein; and
a second dielectric material located atop the first dielectric material, said second dielectric material includes at least one conductively filled opening that is located above said first conductive material, wherein said at least one conductively filled opening and said first conductive material are horizontally separated by a metallic interfacial layer which is present at least within a bottom portion of said at least one conductively filled opening.

2. The interconnect structure of claim 1 wherein said metallic interfacial layer is present on sidewalls of said second dielectric material that laterally abut the bottom portion of the at least one conductively filled opening.

3. The interconnect structure of claim 1 wherein said metallic interfacial layer is a conductive metal that does not form an alloy with said first conductive material, said conductive metal comprises V, Nb, Ta, Fe, Co, Ni, Ru, Rh, Pd, Os, Ir, Pt or In.

4. The interconnect structure of claim 3 wherein said conductive metal comprises Ta, Ru, Ir, In or Rh.

5. The interconnect structure of claim 1 further comprising a diffusion barrier liner located on an upper surface of said metallic interfacial layer and on vertical sidewalls of said second dielectric material that abut said bottom portion of said at least one conductive filled opening.

6. The interconnect structure of claim 5 wherein said diffusion barrier liner comprises a lower layer of a metallic nitride, and an upper layer of a metal.

7. The interconnect structure of claim 6 wherein said metallic nitride is TaN and said metal is Ta.

8. The interconnect structure of claim 1 wherein said at least one conductively filled opening comprises one of a conductive metal, an alloy comprising at least one conductive metal and a conductive metal silicide.

9. The interconnect structure of claim 8 wherein said at least one conductively filled opening comprises a conductive material selected from the group consisting of Cu, Al, W and AlCu.

10. The interconnect structure of claim 1 wherein said first and second dielectric materials comprise the same or different interconnect dielectric material.

11. The interconnect structure of claim 10 wherein said interconnect dielectric material is one of SiO₂, a silsesquioxane, a C doped oxide that includes atoms of Si, C, O and H and a thermosetting polyarylene ether.

12. The interconnect structure of claim 1 further comprising a dielectric capping layer located between said first and second dielectric materials, wherein a portion of said dielectric capping layer extends upon an upper surface of said first conductive material.

13. A method of fabricating an interconnect structure comprising:
forming a first dielectric material having a first conductive material embedded therein;
forming a second dielectric material atop the first dielectric material, said second dielectric material has at least one opening that extends to an upper surface of the first conductive material;
forming a metallic interfacial layer at least within a bottom portion of said at least one opening, said metallic interfacial layer is located at least on said upper surface of said first conductive material;
forming a diffusion barrier liner within said at least one opening and on at least an upper surface of said metallic interfacial layer; and
filling said at least one opening with a second conductive material.

14. The method of claim 13 wherein said forming said metallic interfacial layer comprises a non-selective deposition process.

15. The method of claim 13 wherein said forming said metallic interfacial layer comprises a selective deposition process.

16. The method of claim 13 wherein said forming said metallic interfacial layer comprises selecting a conductive metal that does not form an alloy with said first conductive material.

17. The method of claim 16 wherein said conductive metal comprises one of V, Nb, Ta, Fe, Co, Ni, Ru, Rh, Pd, Os, Ir, Pt or In.

18. The method of claim 17 wherein said forming said diffusion barrier liner comprises first depositing a metallic nitride and second depositing a metal.

19. The method of claim 13 further comprising a planarization step after filling said at least one opening with said second conductive material.

20. The method of claim 13 further comprising forming a dielectric capping layer on said first dielectric material including a surface of said first conductive material, said dielectric capping layer is opened during said forming of said at least one opening.
